(19) United States
(12) Patent Application Publication
(10) Pub. No.: US 2024/0381732 A1
(43) Pub. Date: Nov. 14, 2024

(54) DISPLAY DEVICE AND METHOD OF FABRICATING THE SAME

(71) Applicant: Samsung Display Co., LTD., Yongin-si (KR)

(72) Inventors: Min Uk KIM, Yongin-si (KR); Bo Hwa KIM, Yongin-si (KR); Che Ho LIM, Yongin-si (KR); Kang Uk KIM, Yongin-si (KR); Kwang Min LEE, Yongin-si (KR); Kang Soo HAN, Yongin-si (KR)

(73) Assignee: Samsung Display Co., LTD., Yongin-si (KR)

(21) Appl. No.: 18/426,382

(22) Filed: Jan. 30, 2024

(30) Foreign Application Priority Data
May 11, 2023 (KR) 10-2023-0061148

(51) Int. Cl. H10K 59/38; H10K 59/80

(52) U.S. Cl. CPC H10K 59/38; H10K 59/8722; H10K 59/873

(57) ABSTRACT

A display device that includes a first substrate including a display area and a peripheral area disposed on a side of the display area, a second substrate disposed to face the first substrate, the second substrate including a first surface and a second surface, a pixel circuit layer disposed on the first substrate, a light emitting element disposed on the pixel circuit layer and in the display area, a color conversion layer disposed on the first surface of the second substrate, at least one bank pattern disposed on the first surface of the second substrate, a spacer disposed on the first surface of the second substrate, the spacer enclosed by the at least one bank pattern, a protective layer overlapping the color conversion layer, the at least one bank pattern, and the spacer, and a sealant overlapping at least a portion of the spacer.

### CROSS-REFERENCE TO RELATED APPLICATION(S)

This application claims priority under 35 U.S.C. § 119 from Korean Patent Application No. 10-2023-0061148 filed on May 11, 2023 in the Korean Intellectual Property Office, the entire content of which are incorporated herein by reference.

### BACKGROUND

### 1. Technical Field

Various embodiments of the disclosure relate to a display device and a method of fabricating the display device.

### 2. Description of the Related Art

Recently, as interest in information display increases, research and development on display devices have been continuously conducted.

### SUMMARY

Embodiments provide a display device and a method of fabricating the display device that includes a sealant in a peripheral area disposed at a side of a display area to minimize changes in the spacing between a top substrate and a bottom substrate.

In accordance with an embodiment of the invention, a display device may include a first substrate including a display area and a peripheral area disposed on a side of the display area, a second substrate disposed to face the first substrate the second substrate including a first surface facing the first substrate and a second surface opposite to the first surface, a pixel circuit layer disposed on the first substrate, a light emitting element disposed on the pixel circuit layer in the display area, a color conversion layer disposed on the first surface of the second substrate the color conversion layer overlapping the display area in a plan view, the color conversion layer converting a wavelength of light emitted from the light emitting element, at least one bank pattern disposed on the first surface of the second substrate the at least one bank pattern overlapping the peripheral area in a plan view, a first spacer disposed on the first surface of the second substrate the first spacer enclosed by the at least one bank pattern, a first protective layer overlapping the color conversion layer in a plan view, the at least one bank pattern, and the first spacer, and a sealant overlapping at least a portion of the first spacer in a plan view.

In accordance with an embodiment of the invention, the color conversion layer may include multiple color conversion particles. The first spacer and the color conversion particles may include a same material.

In accordance with an embodiment of the invention, the display device may further include at least one dam structure disposed on the pixel circuit layer and in the peripheral area, the at least one dam structure may be disposed closer to the display area than the sealant. The sealant may not overlap the at least one dam structure in a plan view.

In accordance with an embodiment of the invention, the first spacer and the at least one dam structure may not overlap in a plan view.

In accordance with an embodiment of the invention, the display device may further include a bank disposed on the first surface of the second substrate. The peripheral area may include first to third areas arranged in order of proximity to the display area. The bank may overlap the first area of the peripheral area in a plan view. The at least one dam structure may be disposed in the second area of the peripheral area.

In accordance with an embodiment of the invention, the at least one bank pattern may include a first bank pattern overlapping the third area of the peripheral area in a plan view and enclosing at least a portion of the first spacer. The first protective layer may cover the bank and the first bank pattern.

In accordance with an embodiment of the invention, the first spacer may be disposed between the bank and the first bank pattern.

In accordance with an embodiment of the invention, the at least one bank pattern may further include a second bank pattern overlapping the third area of the peripheral area in a plan view, the second bank pattern may be disposed closer to the display area than the first bank pattern. The first spacer may be disposed between the first bank pattern and the second bank pattern.

In accordance with an embodiment of the invention, the display device may further include a second spacer disposed on the first surface of the second substrate, the second spacer may be disposed between the second bank pattern and the bank.

In accordance with an embodiment of the invention, the display device may further include a second spacer, a third spacer and a fourth spacer disposed on the first surface of the second substrate. The at least one bank pattern may further include a third bank pattern and a fourth bank pattern overlapping the second area of the peripheral area in a plan view. The third bank pattern and the fourth bank pattern may each be spaced apart from the second bank pattern. The second spacer may be disposed between the second bank pattern and the third bank pattern. The third spacer may be disposed between the third bank pattern and the fourth bank pattern. The fourth spacer may be disposed between the fourth bank pattern and the bank.

In accordance with an embodiment of the invention, a display device may include a first substrate including a display area and a peripheral area disposed on a side of the display area, a pixel circuit layer disposed on the first substrate; a light emitting element disposed on the pixel circuit layer and in the display area, a color conversion layer disposed on the light emitting element and in the display area, the color conversion layer converting a wavelength of light emitted from the light emitting element, a spacer disposed on the pixel circuit layer and in the peripheral area, a first protective layer disposed on the first substrate, the first protective layer covering the color conversion layer and the spacer, and a sealant overlapping at least a portion of the spacer in a plan view.

In accordance with an embodiment of the invention, the color conversion layer may include multiple color conversion particles. The first spacer and the color conversion particles may include a same material.

In accordance with an embodiment of the invention, the display device may further include at least one dam structure disposed in the peripheral area, the at least one dam structure being closer to the display area than the sealant.

In accordance with an embodiment of the invention, the spacer may cover the at least one dam structure in a plan view.

In accordance with an embodiment of the invention, the spacer may not overlap the at least one dam structure in a plan view.

In accordance with an embodiment of the invention, the spacer may have a semi-elliptical shape.

In accordance with an embodiment of the invention, the display device may further include an encapsulation layer disposed in the display area, the encapsulation layer may overlap the light emitting element in a plan view, the encapsulation layer may extend to and may be disposed in the peripheral area, and at least one bank pattern disposed on the encapsulation layer and in the peripheral area.

In accordance with an embodiment of the invention, the display device may further include a bank to partition the peripheral area from the display area. The peripheral area may include first to third areas arranged in order of proximity to the display area. The bank may be disposed in the first area. The at least one bank pattern may include a first bank pattern disposed in the third area, the at least one bank pattern may enclose at least a portion of the spacer. The first protective layer may cover the bank and the first bank pattern.

In accordance with an embodiment of the invention, the at least one dam structure may be disposed in the second area. The at least one bank pattern may further include a second bank pattern disposed in the third area and in an area adjacent to the dam structure. The spacer may be disposed between the first bank pattern and the second bank pattern.

In accordance with an embodiment of the invention, the heights of the first bank pattern and the second bank pattern may be lower than a height of the bank.

In accordance with an embodiment of the invention, the display device may further include a filling layer disposed in the display area and extending from an inside of the sealant, and a light conversion layer disposed on the sealant and the filling layer. The light conversion layer may include a second protective layer, a low refractive layer, a color filter layer, and a second substrate that may be successively disposed in a direction.

In accordance with an embodiment of the invention, a method of fabricating a display device may include providing a base substrate including a display area and a peripheral area disposed at a side of the display area, forming a color filter layer on the base substrate, forming at least one partition wall on the color filter layer and in the display area, forming at least one bank pattern on the color filter layer and in the peripheral area, forming a color conversion layer in the display area, forming a spacer in the peripheral area and in an area enclosed by the at least one bank pattern, forming a protective layer that covers the color conversion layer and the spacer; and forming a sealant on the protective layer, the protective layer overlaps the spacer in a plan view.

In accordance with an embodiment of the invention, the spacer and the color conversion layer may be formed in a same process.

### BRIEF DESCRIPTION OF THE DRAWINGS

The above and other features of the disclosure will become more apparent by describing in further detail embodiments thereof with reference to the accompanying drawings.

FIG. 1 is a schematic plan view illustrating a display device in accordance with embodiments of the disclosure;

FIG. 2 is a schematic sectional view illustrating a display panel of FIG. 1;

FIG. 3 is a schematic diagram of an equivalent circuit of a sub-pixel included in the display device of FIG. 1;

FIG. 4 is a schematic sectional view illustrating an embodiment of a display panel that overlaps a display area and a peripheral area of FIG. 1;

FIGS. 5A to 5C are schematic sectional views illustrating other embodiments of the peripheral area of FIG. 4;

FIG. 6 is a schematic sectional view illustrating an embodiment of a display panel that overlaps a display area and a peripheral area of FIG. 1;

FIGS. 7 and 8 are schematic sectional views illustrating other embodiments of the peripheral area of FIG. 6; and

FIGS. 9 to 14 are sectional views schematically illustrating a method of fabricating the display device in accordance with embodiments of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in an embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

As used herein, the term “and/or” includes any and all combinations of one or more of the associated listed items. A description that a component is “configured to” perform a specified operation may be defined as a case where the component is constructed and arranged with structural features that can cause the component to perform the specified operation.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described in more detail with reference to the accompanying drawings.

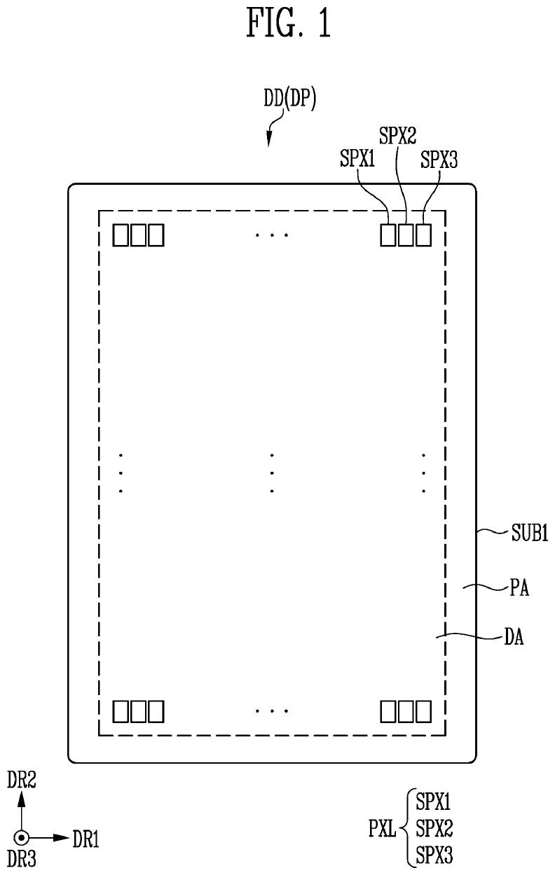

FIG. 1 is a schematic plan view illustrating a display device DD in accordance with embodiments of the disclosure.

Referring to FIG. 1, a display panel DP (or the display device DD) in accordance with an embodiment may be provided in various forms, for example, in the form of a rectangular plate having two pairs of parallel sides, but the disclosure may not be limited thereto. In the case where the display panel DP is provided in the form of a rectangular plate, a pair of sides of the two pairs of sides may be longer than another pair of sides.

At least a portion of the display panel DP may have flexibility, and the display panel DP may be folded on the portion having the flexibility, but the disclosure may not be limited thereto.

The display panel DP may display an image. A self-emissive display panel, such as an organic light emitting display panel (OLED panel) using an organic light emitting diode as a light emitting element, a subminiature light emitting diode (micro-LED or nano-LED) display panel using a subminiature LED as a light emitting element, and a quantum dot organic light emitting display panel (QD OLED panel) using a quantum dot and an organic light emitting diode, may be used as the display panel DP. In addition, a non-emissive display panel such as a liquid crystal display (LCD) panel, an electro-phoretic display (EPD) panel, or an electro-wetting display (EWD) panel may be used as the display panel DP. In case that the non-emissive display panel may be used as the display panel DP, the display device DD may include a backlight unit (or light emitting device) configured to supply light to the display panel DP.

The display panel DP may include a first substrate SUB1, and multiple pixels PXL disposed on the first substrate SUB1.

The first substrate SUB1 may include a transparent insulating material to allow for light transmission. The first substrate SUB1 may be a rigid substrate or a flexible substrate. For example, the rigid substrate may be one of a glass substrate, a quartz substrate, a glass ceramic substrate, a crystalline glass substrate, or a combination thereof.

The flexible substrate may be either a film substrate or a plastic substrate which includes polymeric organic material. For example, the flexible substrate SUB may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

The display device DD may have various shapes. For example, the display device DD may be provided in the form of a rectangular plate, but the disclosure may not be limited thereto. For instance, the display device DD may have a circular shape or an elliptical shape. Furthermore, the display device DD may have an angled corner and/or curved corner. For convenience of explanation, FIG. 1 illustrates that the display device DD has a rectangular plate shape. In addition, in FIG. 1, an extension direction (e.g., a horizontal direction) of a short side of the display device DD may be designated as a first direction DR1, and an extension direction (e.g., a vertical direction) of a long side thereof may be designated as a second direction DR2.

The first substrate SUB1 (or the display device DD) may include a display area DA configured to display an image, and a peripheral area PA (or a non-display area) formed in an area other than the display area DA. The first substrate SUB1 may include a display area DA including multiple pixel areas in which the respective pixels PXL may be disposed, and a peripheral area PA disposed around the perimeter of the display area DA (or adjacent to the display area DA).

The peripheral area PA may be disposed adjacent to the display area DA. The peripheral area PA may be disposed on at least a side of the display area DA. For example, the peripheral area PA may enclose the perimeter (or edges) of the display area DA. In an embodiment, the peripheral area PA may be a bezel area of the display device DD.

The pixels PXL may be disposed in the display area DA on the first substrate SUB1. The peripheral area PA may be disposed around the display area DA. A structure for protecting components included in the pixels PXL disposed in the display area DA may be disposed in the peripheral area PA, but the disclosure may not be limited thereto. For example, in the peripheral area, there may be a line component extended from the respective pixels PXL, and a driver electrically connected to the line component and configured to drive the pixels PXL.

Each pixel PXL may include multiple sub-pixels SPX1 to SPX3. For example, each pixel PXL may include a first sub-pixel SPX1, a second sub-pixel SPX2, and a third sub-pixel SPX3. The first sub-pixel SPX1, the second sub-pixel SPX2, and the third sub-pixel SPX3 may be successively arranged in the first direction DR1. However, the disclosure may not be limited to the foregoing description, and the first sub-pixel SPX1, the second sub-pixel SPX2, and the third sub-pixel SPX3 may instead be successively disposed in the second direction DR2 intersecting the first direction DR1.

The first to third sub-pixels SPX1 to SPX3 may emit different colors of light. For instance, the first sub-pixel SPX1 may be a red sub-pixel configured to emit red light, the second sub-pixel SPX2 may be a green sub-pixel configured to emit green light, and the third sub-pixel SPX3 may be a blue sub-pixel configured to emit blue light. However, the colors, types and/or number of sub-pixels forming each pixel PXL may not be particularly limited. For example, the color of light which may be emitted from each of the first to third sub-pixels SPX1 to SPX3 may be changed in various ways.

Hereinafter, the term “pixel PXL” will be used to collectively designate the first to third sub-pixels SPX1 to SPX3.

The display area DA may include multiple pixels PXL which may be arranged in a matrix form along rows extending in a first direction DR1 and columns extending in a second direction DR2. The arrangement of the pixels PXL may not be limited to a specific example. In the case where multiple pixels PXL may be disposed, the pixels PXL may have different surface areas (or sizes). For example, in the case in which the pixels PXL emit different colors of light, the pixels PXL may have different surface areas (or different sizes) or different shapes by colors.

The driver may provide a signal and a power voltage to each pixel PXL through the line component to control the operation of each pixel PXL.

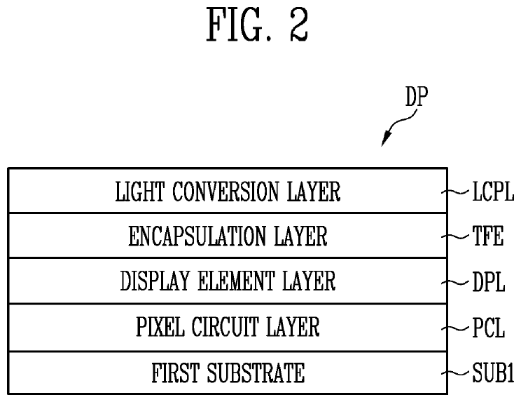

FIG. 2 is a schematic sectional view illustrating the display panel DP of FIG. 1.

The display panel DP may include a pixel circuit layer PCL, a display element layer DPL, an encapsulation layer TFE, and a light conversion layer LCPL which may be disposed on the first substrate SUB1.

The pixel circuit layer PCL may be disposed on the first substrate SUB1, and include multiple transistors and signal lines electrically connected to the transistors. For example, each transistor may have a shape in which a semiconductor pattern, a gate electrode, a source electrode, and a drain electrode may be successively stacked on each other with insulating layers disposed therebetween. The semiconductor pattern may include amorphous silicon, poly silicon, low temperature poly silicon, an organic semiconductor, and/or an oxide semiconductor. Although the gate electrode, the source electrode, and the drain electrode each may include one of aluminum (Al), copper (Cu), titanium (Ti), molybdenum (Mo), and a combination thereof, the disclosure may not be limited thereto. The pixel circuit layer PCL may also include at least one or more insulating layers.

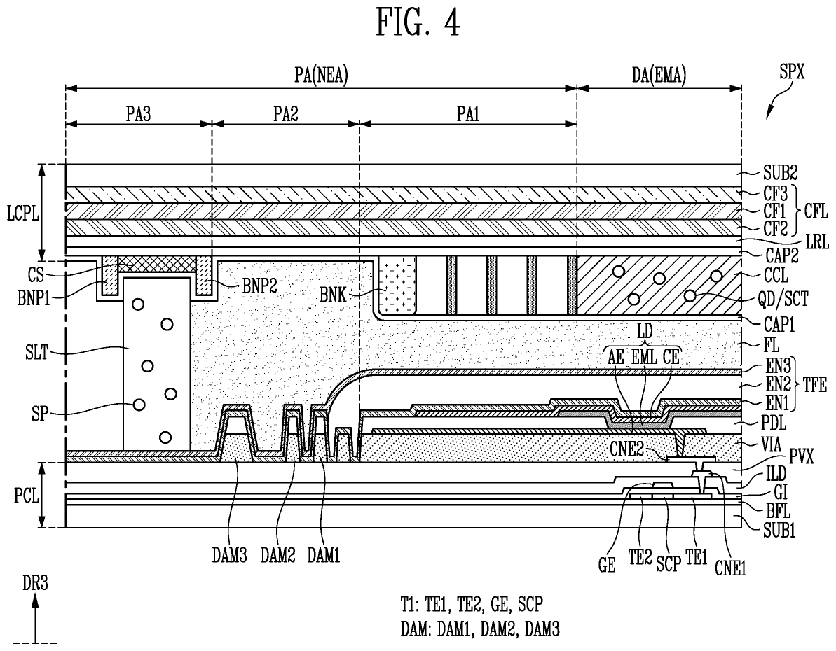

The display element layer DPL may be disposed on the pixel circuit layer PCL. The display element layer DPL may include a light emitting element (e.g., a light emitting element LD of FIG. 4) configured to emit light. Although the light emitting element may be, e.g., an organic light emitting diode, the disclosure may not be limited thereto. In an embodiment, the light emitting element may be an inorganic light emitting element including inorganic light emitting material, or a light emitting element that emits light after changing the wavelength of the light to be emitted using quantum dots.

The encapsulation layer TFE may be disposed on the display element layer DPL. The encapsulation layer TFE may be an encapsulation substrate or have the form of an encapsulation film having a multi-layer structure. In case that the encapsulation layer TFE has the form of the encapsulation film, the encapsulation layer TFE may include an inorganic layer and/or an organic layer. For example, the encapsulation layer TFE may have a structure formed by successively stacking an inorganic layer, an organic layer, and an inorganic layer. The encapsulation layer TFE may prevent external air or water from permeating the display element layer DPL or the pixel circuit layer PCL.

The light conversion layer LCPL may be disposed on the encapsulation layer TFE. The light conversion layer LCPL allows light emitted from the display element layer DPL to selectively pass therethrough, and may include elements for enhancing the light output efficiency. In an embodiment, the light conversion layer LCPL may include a color filter layer (e.g., a color filter layer CFL of FIG. 4), a low refractive layer (e.g., a low refractive layer LRL of FIG. 4), and/or a support substrate (e.g., a second substrate SUB2 of FIG. 4).

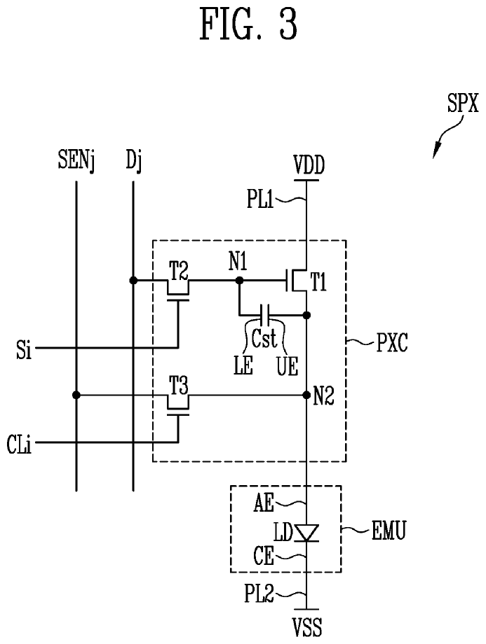

FIG. 3 is a schematic diagram of an equivalent circuit of a sub-pixel SPX included in the display device DD of FIG. 1.

The sub-pixel SPX illustrated in FIG. 3 may be any one of the sub-pixels SPX1 to SPX3 illustrated in FIG. 1. The sub-pixels SPX1 to SPX3 arranged in the display area of the display device DD may have a substantially identical or similar configuration.

For the sake of explanation, FIG. 3 illustrates a sub-pixel SPX disposed on an i-th pixel row (or an i-th horizontal line) and a j-th pixel column (where each of i and j may be a natural number).

Referring to FIGS. 1 to 3, the sub-pixel SPX may include an emission component EMU configured to generate light having a luminance corresponding to a data signal. Furthermore, the sub-pixel SPX may further include a pixel circuit PXC configured to drive the emission component EMU.

The emission component EMU may include a light emitting element LD electrically connected between a first power line PL1 disposed to receive a voltage from a first driving power supply VDD (or a first power supply) and a second power line PL2 disposed to receive a voltage from a second driving power supply VSS (or a second power supply). For example, the emission component EMU may include a light emitting element LD which include a first pixel electrode AE electrically connected to the first driving power supply VDD and the first power line PL1 via the pixel circuit PXC, and a second pixel electrode CE electrically connected to the second driving power supply VSS via the second power line PL2. The first pixel electrode AE may be an anode, and the second pixel electrode CE may be a cathode. The first driving power supply VDD and the second driving power supply VSS may have different potentials. Here, a difference in potential between the first and second driving power supplies VDD and VSS may be set to a value equal to or greater than a threshold voltage of the light emitting elements LD during an emission period of the sub-pixel SPX.

In the case in which the sub-pixel SPX may be disposed on an i-th pixel row and a j-th pixel column in the display area DA, the pixel circuit PXC of the sub-pixel SPX may be electrically connected to an i-th scan line Si and a j-th data line Dj. Furthermore, the pixel circuit PXC may be electrically connected to an i-th control line CLi and a j-th sensing line SENj.

The pixel circuit PXC may include first to third transistors T1 to T3, and a storage capacitor Cst.

The first transistor T1 may be electrically connected between the first driving power supply VDD and the light emitting element LD as a driving transistor to control driving current to be applied to the light emitting element LD. In detail, a first terminal of the first transistor T1 may be electrically connected to the first driving power supply VDD by the first power line PL1. A second terminal of the first transistor T1 may be electrically connected to a second node N2. A gate electrode of the first transistor T1 may be electrically connected to a first node N1. The first transistor T1 may control, in response to a voltage applied to the first node N1, driving current to be applied from the first driving power supply VDD to the light emitting element LD through the second node N2. In an embodiment, the first terminal of the first transistor T1 may be a drain electrode, and the second terminal of the first transistor T1 may be a source electrode, and the disclosure may not be limited thereto. In an embodiment, the first terminal may instead be a source electrode, and the second terminal may instead be a drain electrode.

The second transistor T2 may be electrically connected between the data line Dj (e.g., the j-th data line) and the first node N1 as a switching transistor to select a sub-pixel SPX in response to a scan signal and activate the sub-pixel SPX. A first terminal of the second transistor T2 may be electrically connected to the data line Dj. A second terminal of the second transistor T2 may be electrically connected to the first node N1 (or the gate electrode of the first transistor T1). A gate electrode of the second transistor T2 may be electrically connected to the scan line Si (or the i-th scan line). The first terminal and the second terminal of the second transistor T2 may be different terminals, and, for example, in case that the first terminal is a drain electrode, the second terminal may be a source electrode.

In case that a scan signal having a gate-on voltage (e.g., a high level voltage) is supplied from the scan line Si, the second transistor T2 may be turned on to electrically connect the data line Dj to the first node N1. The first node N1 may be a point at which the second terminal of the second transistor T2 and the gate electrode of the first transistor T1 are electrically connected to each other. The second transistor T2 may transmit a data signal to the gate electrode of the first transistor T1.

The third transistor T3 may obtain a sensing signal through the sensing line SENj by electrically connecting the first transistor T1 to the sensing line SENj (e.g., the j-th sensing line), and detect, using the sensing signal, characteristics of the sub-pixel SPX such as a threshold voltage of the first transistor T1. Information about the characteristics of each sub-pixel SPX may be used to convert image data such that a deviation in characteristics between sub-pixels SPX can be compensated for. A second terminal of the third transistor T3 may be electrically connected to the second terminal of the first transistor T1. A first terminal of the third transistor T3 may be electrically connected to the sensing line SENj. A gate electrode of the third transistor T3 may be electrically connected to the control line CLi (e.g., the i-th control line). The first terminal may be a drain electrode, and the second terminal may be a source electrode.

The third transistor T3 may be an initialization transistor configured to initialize the second node N2, and may be turned on in case that a sensing control signal is supplied thereto from the control line CLi, so that the voltage of the initialization power supply can be transmitted to the second node N2. Hence, the storage capacitor Cst which may be electrically connected to the second node N2 may be initialized.

The storage capacitor Cst may include a lower electrode LE (or a first storage electrode) and an upper electrode UE (or a second storage electrode). The lower electrode LE may be electrically connected to the first node N1. The upper electrode UE may be electrically connected to the second node N2. The storage capacitor Cst may be charged with a data voltage corresponding to a data signal to be supplied to the first node N1 during a frame period. Hence, the storage capacitor Cst may store a voltage corresponding to a difference between a voltage of the gate electrode of the first transistor T1 and a voltage of the second node N2.

Although FIG. 3 illustrates an embodiment where all of the first to third transistors T1 to T3 may be N-type transistors, the disclosure may not be limited thereto. For example, at least one of the first to third transistors T1 to T3 may instead be changed to a P-type transistor. The structure of the pixel circuit PXC may also be changed in various ways.

In the following embodiments, for convenience of explanation, a transverse direction (or an X-axis direction or a horizontal direction) in a plan view will be indicated by a first direction DR1, a longitudinal direction (or a Y-axis direction or a vertical direction) in a plan view will be indicated by a second direction DR2, and a vertical direction in a sectional view will be indicated by a third direction DR3.

FIG. 4 is a schematic sectional view illustrating an embodiment of a display panel that overlaps the display area DA and the peripheral area PA of FIG. 1.

Referring to FIG. 4, the display device may include a first substrate SUB1 (or a bottom substrate) including the display area DA and the peripheral area PA. The sub-pixel SPX may be disposed in the display area DA.

The sub-pixel SPX may include a pixel circuit layer PCL, a light emitting element LD, and an encapsulation layer TFE, which may be successively disposed on the first substrate SUB1.

In the pixel circuit layer PCL, there may be disposed circuit elements (e.g., the first to third transistors T1 to T3 of FIG. 3), and signal lines that may be electrically connected to the circuit elements. The pixel circuit layer PCL may be disposed on the first substrate SUB1. The pixel circuit layer PCL may include a first transistor T1, a buffer layer BFL, a gate insulating layer GI, an interlayer insulating layer ILD, a passivation layer PVX, and a via layer VIA. As an example, although one transistor T1 may be illustrated, the sub-pixel SPX may include multiple transistors and at least one capacitor to drive the light emitting element LD.

The buffer layer BFL may be disposed on the first substrate SUB1. The buffer layer BFL may prevent impurities from diffusing from the outside. The buffer layer BFL may prevent impurities from being diffused into the first transistor T1 disposed on the first substrate SUB1, and may enhance planarization of the first substrate SUB1. The buffer layer BFL may be disposed in the form of a single layer structure, or disposed in the form of a multilayer structure. The buffer layer BFL may be an inorganic insulating layer including inorganic material. The inorganic insulating layer may include, for example, at least one of silicon nitride (SiNₓ), silicon oxide (SiOₓ), silicon oxynitride (SiON), and metal oxide such as aluminum oxide (AlOₓ). In the case where the buffer layer BFL may be disposed in the form of a multilayer structure, the respective layers may be formed of the same material or of different materials. The buffer layer BFL may be omitted in some cases.

The first transistor T1 may include a semiconductor pattern SCP, a gate electrode GE, a first electrode TE1, and a second electrode TE2. The first electrode TE1 may be either a source electrode or a drain electrode, and the second electrode TE2 may be another electrode. For example, in case that the first electrode TE1 may be a drain electrode, the second electrode TE2 may be a source electrode.

The semiconductor pattern SCP may be disposed and/or formed on the buffer layer BFL. The semiconductor pattern SCP may include a first area that contacts the first electrode TE1, a second area that contacts the second electrode TE2, and a channel area formed between the first area and the second area. The channel area may overlap the gate electrode GE of the first transistor T1. The semiconductor pattern SCP may be a semiconductor pattern formed of amorphous silicon, polysilicon, low-temperature polysilicon, an oxide semiconductor, an organic semiconductor, a combination thereof, or the like. For example, the channel area may be an undoped semiconductor pattern without impurities, and may be an intrinsic semiconductor. Each of the first area and the second area may be a semiconductor pattern doped with impurities. In an embodiment, the first electrode TE1 may be electrically connected to the light emitting element LD through connection electrodes CNE1 and CNE2.

The gate insulating layer GI may be disposed and/or formed on the semiconductor pattern SCP. The gate insulating layer GI may be an inorganic insulating layer including inorganic material. The gate insulating layer GI may include the same material as that of the buffer layer BFL, or include one or more materials selected from among the materials exemplified as the constituent materials of the buffer layer BFL. For example, the gate insulating layer GI may be formed of an inorganic insulating layer including an inorganic material. Although the gate insulating layer GI may be disposed in a single-layer structure, the gate insulating layer GI may be disposed in a multilayer structure having at least two or more layers.

The gate electrode GE may be disposed and/or formed on the gate insulating layer GI to correspond to the channel area of the semiconductor pattern SCP. The gate electrode GE may be disposed on the gate insulating layer GI and overlap the channel area of the semiconductor pattern SCP. The gate electrode GE may have a single layer structure formed of one or combination of materials selected from the group consisting of copper (Cu), molybdenum (Mo), tungsten (W), aluminum neodymium (AlNd), titanium (Ti), aluminum (Al), silver (Ag), and an alloy thereof, or may have a double layer or multilayer structure formed of molybdenum (Mo), titanium (Ti), copper (Cu), aluminum (Al), or silver (Ag) to reduce line resistance.

The interlayer insulating layer ILD may be disposed and/or formed on the gate electrode GE. The first connection electrode CNE1 may be disposed on the interlayer insulating layer ILD. The first connection electrode CNE1 may be electrically connected to the first electrode TE1 through a contact hole (not illustrated) that passes through the gate insulating layer GI and the interlayer insulating layer ILD.

The passivation layer PVX may be disposed and/or formed on the first connection electrode CNE1. The second connection electrode CNE2 may be disposed on the passivation layer PVX. The second connection electrode CNE2 may be electrically connected to the first connection electrode CNE1 through a contact hole (not illustrated) that passes through the passivation layer PVX.

The passivation layer PVX may be disposed in the form of a structure including an inorganic insulating layer disposed on an organic insulating layer, or a structure including an organic insulating layer disposed on an inorganic insulating layer. The inorganic insulating layer may include, for example, at least one of silicon oxide (SiOₓ), silicon nitride (SiNₓ), silicon oxynitride (SiOₓN_{y}), and metal oxide such as aluminum oxide (AlOₓ). The organic insulating layer may include, for example, at least one of polyacrylate resin, epoxy resin, phenolic resin, polyamide resin, polyimide resin, unsaturated polyester resin, poly-phenylene ether resin, poly-phenylene sulfide resin, and benzocyclobutene resin.

The via layer VIA may be disposed and/or formed on the overall surface of the passivation layer PVX. The via layer VIA may be an inorganic insulating layer including inorganic material or an organic insulating layer including organic material.

The light emitting element LD and the pixel defining layer PDL may be disposed and/or formed on the via layer VIA.

In an embodiment, the light emitting element LD may include a first pixel electrode AE, an emission layer EML, and a second pixel electrode CE. The light emitting element LD may be electrically connected to a pixel circuit (e.g., the pixel circuit PXC of FIG. 3) of the corresponding pixel.

The first pixel electrode AE may be disposed and/or formed on the via layer VIA of the corresponding pixel. The first pixel electrode AE may be an anode electrode of the light emitting element LD. The first pixel electrode AE may be electrically connected to the first electrode TE1 through a corresponding contactor (not illustrated).

The first pixel electrode AE may be formed of conductive material (or substance). The conductive material may include opaque metal. For example, the opaque metal may include metal such as silver (Ag), magnesium (Mg), aluminum (Al), platinum (Pt), palladium (Pd), gold (Au), nickel (Ni), neodymium (Nd), iridium (Ir), chrome (Cr), titanium (Ti), an alloy thereof, or a combination thereof. However, the material of the first pixel electrode AE may not be limited to the foregoing embodiment. In an embodiment, the first pixel electrode AE may instead include transparent conductive material (or substance). The transparent conductive material (or substance) may include transparent conductive oxides such as indium tin oxide (ITO), indium zinc oxide (IZO), zinc oxide (ZnOₓ), indium gallium zinc oxide (IGZO), and indium tin zinc oxide (ITZO), a conductive polymer such as PEDOT (poly(3,4-ethylenedioxythiophene)), or a combination thereof. If the first pixel electrode AE includes transparent conductive material (or substance), a separate conductive layer made of opaque metal may be disposed to reflect light emitted from the emission layer EML to an image display direction (or in a direction toward the encapsulation layer TFE) of the display device (e.g., the display device DD of FIG. 1). The first pixel electrode AE may be disposed in the emission area EMA.

The pixel defining layer PDL may define (or partition) the emission area EMA. The pixel-defining layer PDL may be an organic insulating layer made of an organic material. In an embodiment, the pixel defining layer PDL may include light absorbing material or be coated with light absorbing material, so that the pixel defining layer PDL can function to absorb light introduced from the outside. For example, the pixel defining layer PDL may include carbon-based black pigment. The disclosure may not be limited thereto.

The pixel defining layer PDL may be partially open to include an opening (not illustrated) through which an area of the first pixel electrode AE may be exposed. The pixel defining layer PDL may protrude from the via layer VIA in the third direction DR3 along the periphery of the emission area EMA. The pixel defining layer PDL may be disposed on the via layer VIA to define an area where the emission layer EML contacts the first pixel electrode AE. The emission layer EML may be disposed on a portion of the first pixel electrode AE that is exposed through the opening of the pixel defining layer PDL.

The emission layer EML may be disposed in the opening of the pixel defining layer PDL, above both the first pixel electrode AE and the pixel defining layer PDL, but may not be limited thereto. The emission layer EML may instead be disposed only above the first pixel electrode AE in the opening of the pixel definition layer PDL.

The emission layer EML may have a multilayer thin-film structure including a light generation layer to generate light. The emission layer EML may emit one of red light, green light, and blue light, but may not be limited thereto. The emission layer EML may have a multilayer thin-film structure including a light generation layer. The emission layer EML may include a hole injection layer into which holes may be injected, a hole transport layer which has excellent hole transportation performance and restrains movement of electrons that have not been coupled with holes in the light generation layer and thus increases chances of recombination between holes and electrons, the light generation layer which emits light by recombination between injected electrons and holes, a hole blocking layer which restrains movement of holes that have not been coupled with electrons in the light generation layer, an electron transport layer which may be disposed to smoothly transport electrons to the light generation layer, and an electron injection layer into which electrons may be injected. The emission layer EML may emit light based on an electrical signal which may be provided by the first pixel electrode AE and the second pixel electrode CE.

The second pixel electrode CE may be disposed on the emission layer EML and the pixel defining layer PDL. The second pixel electrode CE may be disposed in the form of a plate corresponding to an overall area of the display area DA.

The second pixel electrode CE may be a thin metal layer having a thickness sufficient to allow light emitted from the emission layer EML to transmit therethrough. The second pixel electrode CE may be made of a metal material or a transparent conductive material to have a relatively small thickness. The second pixel electrode CE may include at least one of various transparent conductive materials including indium tin oxide, indium zinc oxide, indium tin zinc oxide, aluminum zinc oxide, gallium zinc oxide, zinc tin oxide, or gallium tin oxide, and may be substantially transparent or translucent to provide satisfactory light transmittance. Hence, light emitted from the emission layer EML disposed under the second pixel electrode CE may be emitted in a direction toward an upper surface of the encapsulation layer TFE through the second pixel electrode CE.

The encapsulation layer TFE may be disposed and/or formed on the overall surface of the second pixel electrode CE.

The encapsulation layer TFE may include first to third layers EN1 to EN3 which may be successively disposed on the second pixel electrode CE. The first layer EN1 and the third layer EN3 may be inorganic layers including inorganic material. The second layer EN2 may be an organic layer including organic material. The first layer EN1 and the third layer EN3 may protect the sub-pixel SPX from water and oxygen. The second layer EN2 may protect the sub-pixel SPX from foreign substances such as dust particles.

The light conversion layer LCPL may be disposed on the encapsulation layer TFE. In an embodiment, the light conversion layer LCPL may include a bank BNK, a first protective layer CAP1, a color conversion layer CCL, a second protective layer CAP2, a low refractive layer LRL, a color filter layer CFL, and a second substrate SUB2.

In an embodiment, the light conversion layer LCPL may be disposed to be spaced apart from the first substrate SUB1. In an embodiment, the second substrate SUB2 (or a top substrate) may be spaced apart from the first substrate SUB1 in the third direction DR3, and may be disposed to face the first substrate SUB1. The second substrate SUB2 may include a first surface SF1 facing the first substrate SUB1, and a second surface SF2 opposite to the first surface. The second substrate SUB2 may include inorganic material or organic material. The second substrate SUB2 may generally cover components disposed on the first surface, thus preventing infiltration of water or moisture from the external environment.

The second substrate SUB2 may have a multilayer structure. For example, the second substrate SUB2 may include at least two inorganic layers, and at least one organic layer disposed between the at least two inorganic layers. Here, the constituent material and/or structure of the second substrate SUB2 may be changed in various ways. At least one overcoat layer and/or a filler layer may be additionally disposed on the second surface of the second substrate SUB2. In an embodiment, the second substrate SUB2 may form the top substrate of the display device.

In an embodiment, the color filter layer CFL, the low refractive layer LRL, the second protective layer CAP2, the color conversion layer CCL, and the first protective layer CAP1 may be successively disposed on the first surface of the second substrate SUB2.

The color filter layer CFL may be disposed on the first surface (or the lower surface) of the second substrate SUB2. The color filter layer CFL may include color filter material that allows a specific color of light converted by the color conversion layer CCL to selectively pass therethrough. The color filter layer CFL may include first to third color filters CF1 to CF3. The first color filter CF1 may be a red color filter. The second color filter CF2 may be a green color filter. The third color filter CF3 may be a blue color filter. In the case where the corresponding sub-pixel SPX may be a red pixel, the first color filter CF1 may be disposed in the color conversion layer CCL. It is to be appreciated that FIG. 4 illustrates all three color filters CF1, CF2 and CF3 disposed at a location corresponding to the sub-pixel or opening in the pixel defining layer PDL due to a location of the cross section of FIG. 4.

The first to third color filters CF1 to CF3 may be disposed to extend from the display area DA to the peripheral area PA. In an embodiment, a separate light blocking pattern in lieu of a stack structure of the first to third color filters CF1 to CF3 may be disposed in the peripheral area PA.

A low refractive layer LRL may be disposed under the color filter layer CFL. The low refractive layer LRL may totally reflect light (e.g., light traveling in a diagonal direction) emitted from the color conversion layer CCL, and enhance the light output efficiency of the sub-pixel SPX. To achieve the foregoing purposes, the low refractive layer LRL may have a relatively low refractive index compared to that of the color conversion layer CCL. In an embodiment, the low refractive layer LRL may mitigate a step difference formed by components disposed thereunder, thus providing a planar surface.

The second protective layer CAP2 may be disposed under the low refractive layer LRL. The second protective layer CAP2 may prevent water from permeating the low refractive layer LRL.

In an embodiment, the bank BNK and the color conversion layer CCL may be disposed under the second protective layer CAP2.

The bank BNK may be disposed under the second protective layer CAP2, and may be disposed in an area corresponding to the peripheral area PA. The bank BNK may be disposed in the peripheral area PA adjacent to the display area DA. In an embodiment, the bank BNK may be disposed in a boundary area between the display area DA and the peripheral area PA.

The bank BNK may be a structure that defines a position, to which the color conversion layer CCL may be to be supplied, and prevents the color conversion layer CCL from being drawn into the peripheral area PA. The bank BNK may include organic material. In some embodiments, the bank BNK may include light blocking material. The light blocking material may be a black matrix. The bank BNK may include at least one light blocking material and/or reflective material, and allow light emitted from the color conversion layer CCL to more reliably travel in the image display direction (or the third direction DR3) of the display device, thus enhancing the light output efficiency of the color conversion layer CCL.

The color conversion layer CCL may be disposed under the second protective layer CAP2, and may be disposed in an area that overlaps the display area DA. The color conversion layer CCL may include color conversion particles QD (or wavelength conversion particles) corresponding to a specific color. For example, the color conversion layer CCL may include color conversion particles QD configured to convert a first color of light (or light in a first wavelength band) that may be incident thereon from the light emitting element LD to a second color of light (or a specific color of light, or light in a second wavelength band) and emit the converted light.

In the case in which the sub-pixel SPX may be a red pixel (or a red sub-pixel), the color conversion particles QD of the sub-pixel SPX may include color conversion particles formed of red quantum dots which convert the first color of light emitted from the light emitting element LD to the second color of light (e.g., red light).

In the case in which the sub-pixel SPX may be a green pixel (or a green sub-pixel), the color conversion particles QD of the sub-pixel SPX may include color conversion particles formed of green quantum dots which convert the first color of light emitted from the light emitting element LD to the second color of light (e.g., green light).

In the case where the sub-pixel SPX may be a blue pixel (or a blue sub-pixel) and the light emitting element LD emits blue-based light, the sub-pixel SPX may include a light scattering layer including light scattering particles SCT. The light scattering layer may be omitted depending on the embodiment. In an embodiment, in the case where the sub-pixel SPX may be a blue pixel, a transparent polymer may be disposed in lieu of the color conversion layer CCL.

The first protective layer CAP1 may be disposed under the color conversion layer CCL, and may prevent water or foreign substances from infiltrating into the color conversion layer CCL. The first protective layer CAP1 may include inorganic material. The first protective layer CAP1 may cover the color conversion layer CCL and be disposed to extend into the peripheral area PA.

Referring to FIG. 4, some components disposed in the display area DA may extend to the peripheral area PA and be disposed in the peripheral area PA. In an embodiment, in the peripheral area PA, there may be disposed the buffer layer BFL, the gate insulating layer GI, the interlayer insulating layer ILD, and the passivation layer PVX that may be included in the pixel circuit layer PCL. The via layer VIA may be disposed to extend to an area of the peripheral area PA. For example, first to third layers EN1 to EN3 as well as the light emitting element LD, the pixel defining layer PDL, and the encapsulation layer TFE may be extended to and disposed in the peripheral area PA.

In an embodiment, in the peripheral area PA, there may be disposed the bank BNK, at least one bank pattern BNP1 and/or BNP2, a spacer CS, and a sealant SLT on the first surface SF1 of the second substrate SUB2, and there may be disposed a plurality dam structures DAM1 to DAM3 on the first substrate SUB1.

In an embodiment, the peripheral area PA may include first to third areas PA1 to PA3 that may be arranged in order of the proximity to the display area DA.

In an embodiment, the first area PA1 may be adjacent to the display area DA. Some components that may be disposed in the display area DA may be extended and disposed in the first area PA1. The first area PA1 may be an area where the via layer VIA disposed in the display area DA may be extended to and be disposed in the peripheral area PA. The pixel defining layer PDL, the light emitting element LD, and/or the encapsulation layer TFE may be extended and disposed on the via layer VIA that extends to the first area PA1. In an embodiment, the bank BNK may be disposed in the first area PA1. The bank BNK may be disposed under the second protective layer CAP2 that overlaps the first area PA1. The first protective layer CAP1 may extend from the display area DA and cover the bank BNK that may be disposed in the first area PA1.

In an embodiment, the second area PA2 may be spaced apart from the display area DA, with the first area PA1 disposed therebetween. In the second area PA2, there may also be disposed multiple dam structures DAM1 to DAM3. The dam structures DAM1 to DAM3 may be disposed on the pixel circuit layer PCL on the first substrate SUB1. For example, the dam structures DAM1 to DAM3 may be disposed (e.g., directly disposed) on the passivation layer PVX.

In an embodiment, the dam structures DAM1 to DAM3 may include first to third dam structures DAM1 to DAM3 that may be successively spaced apart from the display area DA. Although FIG. 4 illustrates that three dam structures may be disposed, the disclosure may not be limited thereto. The dam structures may instead include only one or two dam structures, or may instead include four or more dam structures. For example, the first to third dam structures DAM1 to DAM3 and the via layer VIA may be a same layer. The first to third dam structures DAM1 to DAM3 may be successively arranged to be spaced apart from the via layer VIA by certain distances, the via layer VIA being disposed in the first area PA1. Each of the first to third dam structures DAM1 to DAM3 may have a trapezoidal cross-sectional shape that may be reduced in width upward in the third direction DR3. In an embodiment, each of the first to third dam structures DAM1 to DAM3 may include a curved surface having a cross-sectional shape such as a semi-elliptical shape or a semi-circular shape (or a hemispherical shape) which may be reduced in width upward in the third direction DR3. In a cross-sectional view, the shape of each of the first to third dam structures DAM1 to DAM3 may not be limited to the foregoing embodiments, and may be changed in various ways so long as the second layer EN2 of the encapsulation layer TFE can be prevented from overflowing into the peripheral area PA spaced apart from the display area DA by a certain distance. For example, the first to third dam structures DAM1 to DAM3 may be covered by the first layer EN1 and the third layer EN3 of the encapsulation layer TFE. The first layer EN1 and the third layer EN3 may have surface profiles corresponding to the shapes of the first to third dam structures DAM1 to DAM3.

In an embodiment, the third area PA3 may be spaced apart from the display area DA, with the first area PA1 and the second area PA2 disposed therebetween. The third area PA3 may be spaced apart from the display area DA, and may be an outermost area of the display device (e.g., the display device DD of FIG. 1). In the third area PA3, there may be disposed the first spacer CS, the sealant SLT, and at least one bank pattern BNP1 and/or BNP2.

In an embodiment, at least one bank pattern BNP1 and/or BNP2 may include a first bank pattern BNP1 and a second bank pattern BNP2. At least one bank pattern BNP1 and/or BNP2 may be disposed under the second protective layer CAP2 of the second substrate SUB2. In an embodiment, the first and second bank patterns BNP1 and BNP2 may be structures that define a position to which the first spacer CS is to be supplied. In an embodiment, the first bank pattern BNP1 and the second bank pattern BNP2 may be disposed in the third area PA3 at locations spaced apart from each other. For example, the second bank pattern BNP2 may be disposed closer to the display area DA than the first bank pattern BNP1.

In an embodiment, the first spacer CS may be disposed in the third area PA3 of the peripheral area PA to enclose the display area DA. The first spacer CS may be disposed under the second protective layer CAP2 in an area enclosed by the first and second bank patterns BNP1 and BNP2. The first spacer CS may include organic material or inorganic material. In an embodiment, the first spacer CS and the color conversion layer CCL may include a same material. The first spacer CS may and the color conversion particles QD (or the wavelength conversion particles) of the color conversion layer CCL may include a same material.

In an embodiment, the first spacer CS may be disposed and/or formed by an inkjet printing method. As the first spacer CS may be disposed by the inkjet printing method, the height of the first spacer CS may be determined based on the amount of material to be provided.

In an embodiment, the first spacer CS may have surface (or meniscus) characteristics determined by surface tension. For instance, the first and second bank patterns BNP1 and BNP2 may raise a surface film of the first spacer CS, thus allowing the first spacer CS to have a concave meniscus shape. It is to be appreciated that this is just one embodiment, as the materials chosen for the spacer and the first and second bank patterns BNP1 and BNP2 can be chosen so that there is no appreciable meniscus, surface tension or concavity.

In an embodiment, the height of the first and second bank patterns BNP1 and BNP2 in the third direction DR3 may be determined depending on the height of the first spacer CS. In an embodiment, the height of the first spacer CS may be less than that of the first and second bank patterns BNP1 and BNP2.

In an embodiment, the first and second bank patterns BNP1 and BNP2 and the first spacer CS may be covered with the first protective layer CAP1. The first protective layer CAP1 may have a surface profile corresponding to the respective shapes of the first and second bank patterns BNP1 and BNP2 and the first spacer CS.

In an embodiment, the sealant SLT may be disposed between the first spacer CS and the first substrate SUB1 to enclose the display area DA. The sealant SLT may be disposed under the first protective layer CAP1 to overlap the first spacer CS in a plan view, and may extend in the third direction DR3 and contact the first substrate SUB1 (or the encapsulation layer TFE). The sealant SLT may be disposed along a perimeter of the peripheral area PA to seal a filling layer FL from external environment, as water or oxygen could potentially penetrate from the sides of the first substrate SUB1 and the second substrate SUB2.

In an embodiment, the sealant SLT may be disposed in the third area PA3, and may not overlap the damp structures DAM1 to DAM3 in a plan view. However, the disclosure may not be limited to the foregoing embodiment. For example, the sealant SLT may instead extend to the second area PA2 and overlap at least some of the damp structures DAM1 to DAM3.

At least a portion of the sealant SLT may be disposed in space enclosed by the first and second bank patterns BNP1 and BNP2, but the disclosure may not be limited thereto. For example, in the case where the first spacer CS may be formed to have a height similar to that of the first and second bank patterns BNP1 and BNP2, the sealant SLT may not be disposed in the space enclosed by the first and second bank patterns BNP1 and BNP2.

As the sealant SLT may be disposed between the first substrate SUB1 and the second substrate SUB2, the spacing between the first substrate SUB1 and the second substrate SUB2 may be secured. In an embodiment, the sealant SLT may include UV-curable material. In the sealant SLT, there may be disposed multiple support particles SP to reinforce support force of the sealant SLT. The support particles SP may include organic material or inorganic material.

In an embodiment of the disclosure, because the height of the first spacer CS that overlaps the sealant SLT may be flexibly controlled depending on design conditions of the display device, the spacing between the first substrate SUB1 and the second substrate SUB2 may be secured. Furthermore, the presence of the first spacer CS may assist in reducing restorative stress of the sealant SLT, thus minimizing changes in the spacing between the first substrate SUB1 and the second substrate SUB2.

The display device in accordance with an embodiment of the disclosure may provide improved reliability by mitigating (or minimizing) problems such as occurrence of cracks, moisture infiltration defects, deformation of the sealant SLT, and/or occurrence of defective areas in the peripheral area PA, which may be caused by structural deformation due to changes in the spacing between the first substrate SUB1 and the second substrate SUB2.

Furthermore, the first spacer CS functions to mitigate stress on the sealant SLT during a process of bonding the second substrate SUB2 to the first substrate SUB1, thus minimizing (or preventing) occurrence of cracks or the like.

In an embodiment, the filling layer FL may be disposed between the first substrate SUB1 and the second substrate SUB2. The filling layer FL may overlap the display area DA, and may extend to the peripheral area PA and contact the sealant SLT. In an embodiment, the filling layer FL may include filling material that fills space between the encapsulation layer TFE on the first substrate SUB1 and the first protective layer CAP1 on b the second substrate SUB2. The filling material may include silicon, epoxy, and acrylic thermosetting materials.

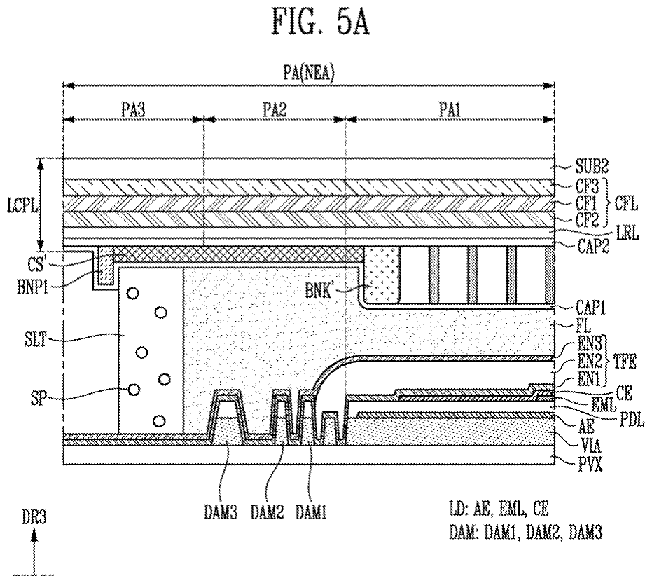

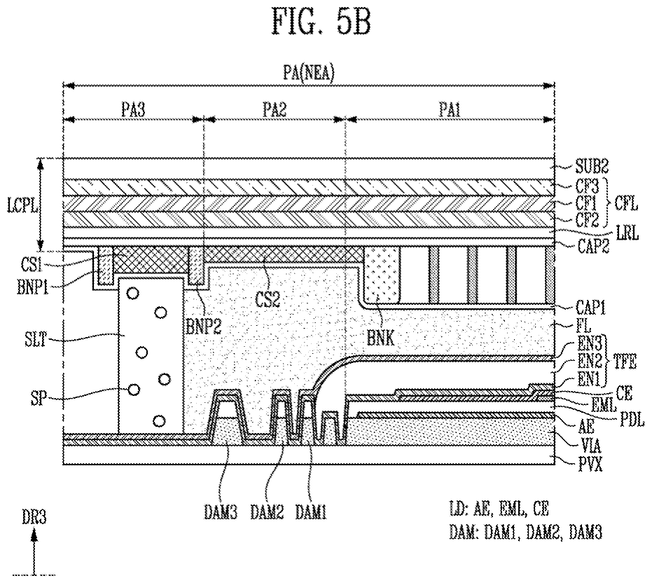

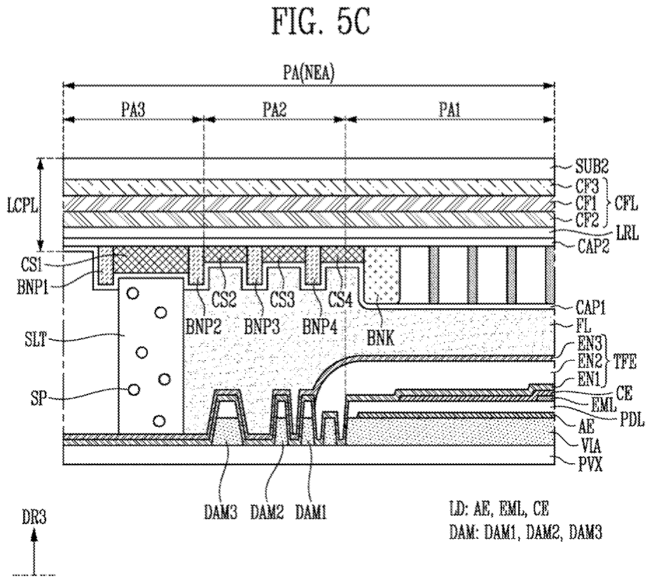

FIGS. 5A to 5C are schematic sectional views illustrating other embodiments of the peripheral area of FIG. 4.

The following description with reference to the embodiments of FIGS. 5A to 5C will be focused on differences from the above-mentioned embodiments (e.g., the embodiment of FIG. 4) so as to avoid redundant description.

Referring to FIG. 5A, except a first spacer CS′ and a bank BNK′, the remaining components may be identical to or correspond to the components illustrated in FIG. 4.

Referring to FIG. 5A, in the third area PA3, there may be disposed the first spacer CS′, the sealant SLT, and the first bank pattern BNP1. The first spacer CS′ may be disposed between the first bank pattern BNP1 and the bank BNK′. The first spacer CS′ may be applied to an overall surface of a lower surface of the second protective layer CAP2 in an area formed between the first bank pattern BNP1 and the bank BNK′. The first spacer CS′ may be disposed in an area overlapping the second area PA2. In an embodiment, the first spacer CS′ may overlap the dam structures DAM1 to DAM3 in a plan view. Although FIG. 5A illustrates that the first spacer CS′ extends from the second area PA2 to the third area PA3 where the first bank pattern BNP1 is disposed, the first spacer CS′ may also be disposed in the first area PA1 adjacent to the display area DA depending on the location of the bank BNK′ disposed in the first area PA1. In an embodiment, the first spacer CS′ may be covered by the first protective layer CAP1. The first protective layer CAP1 may have a surface profile corresponding to the respective shapes of the first bank pattern BNP1, the bank BNK′, and the first spacer CS′.

Referring to FIG. 5B, except a first spacer CS1 and a second spacer CS2, the remaining components may be identical to or correspond to the components illustrated in FIG. 4.

Referring to FIG. 5B, multiple dam structures DAM1 to DAM3 and the second spacer CS2 may be disposed in the second area PA2. In the third area PA3, there may be disposed the first spacer CS1, the sealant SLT, and at least one bank pattern BNP1 and/or BNP2. The first spacer CS1 may correspond to the first spacer CS of FIG. 4. In an embodiment, the second spacer CS2 may be disposed between the second bank pattern BNP2 and the bank BNK. The second spacer CS2 may be applied to a lower surface of the second protective layer CAP2 in an area formed between the second bank pattern BNP2 and the bank BNK. The second spacer CS2 may be disposed in an area overlapping the second area PA2. In an embodiment, the second spacer CS2 may overlap the dam structures DAM1 to DAM3 in a plan view.

In an embodiment, the second spacer CS2 and the first spacer CS1 may include a same material, but the disclosure may not be limited thereto. In an embodiment, the second spacer CS2 may have the same height as the first spacer CS1, but the disclosure may not be limited thereto. For example, the height of the first spacer CS1 may instead be greater than that of the second spacer CS2. In an embodiment, the first and second spacers CS1 and CS2 may be covered with the first protective layer CAP1. The first protective layer CAP1 may have a surface profile corresponding to the shapes of the first and second bank patterns BNP1 and BNP2, the bank BNK, and the first and second spacers CS1 and CS2.

Referring to FIG. 5C, except first to fourth spacers CS1 to CS4 and third and fourth bank patterns BNP3 and BNP4, the remaining components may be identical to or correspond to the components illustrated in FIG. 4.

Referring to FIG. 5C, in the second area PA2, there may be disposed the second to fourth spacers CS2 to CS4 and the third and fourth bank patterns BNP3 and BNP4 along with the dam structures DAM1 to DAM3. In the third area PA3, there may be disposed the first spacer CS1, the sealant SLT, and at least one bank pattern BNP1 and/or BNP2. The first spacer CS1 may correspond to the first spacer CS of FIG. 4. In an embodiment, the first to fourth bank patterns BNP1 to BNP4 may be successively disposed in the peripheral area PA to be spaced apart from each other. The third bank pattern BNP3 and the fourth bank pattern BNP4 may be disposed in the second area PA2 to be spaced apart from the bank BNK. The third bank pattern BNP3 may be disposed at a location spaced apart from the bank BNK by a greater distance than the fourth bank pattern BNP4. In an embodiment, the first to fourth spacers CS1 to CS4 may be disposed between the first to fourth bank patterns BNP1 to BNP4 and the bank BNK. The first spacer CS1 may be disposed between the first bank pattern BNP1 and the second bank pattern BNP2. The second spacer CS2 may be disposed between the second bank pattern BNP2 and the third bank pattern BNP3. The third spacer CS3 may be disposed between the third bank pattern BNP3 and the fourth bank pattern BNP4. The fourth spacer CS4 may be disposed between the fourth bank pattern BNP4 and the bank BNK. The first to fourth spacers CS1 to CS4 may be formed through a same process, and may include a same material. The first to fourth spacers CS1 to CS4 may have a same height, but the disclosure may not be limited thereto. For example, the height of the first spacer CS1 may instead be greater than that of the second to fourth spacers CS2 to CS4.

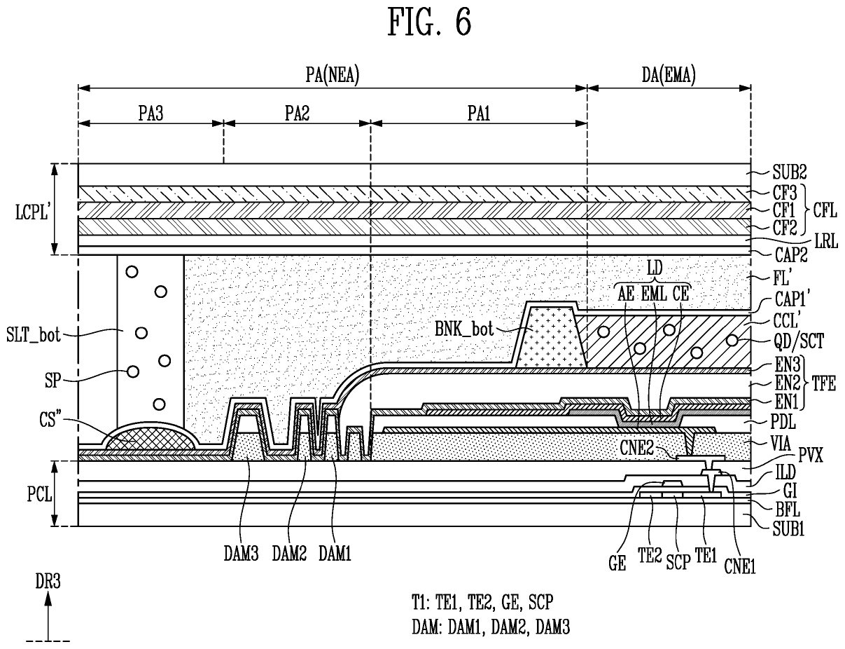

FIG. 6 is a schematic sectional view illustrating an embodiment of the display panel that overlaps the display area DA and the peripheral area PA of FIG. 1.

Except a light conversion layer LCPL′, a color conversion layer CCL′, a filling layer FL′, a bank BNK_bot, a first spacer CS″, and a sealant SLT_bot, the remaining components may be identical to or correspond to the components illustrated in FIG. 4 and therefore redundant explanation thereof will be omitted.

Referring to FIG. 6, the display device may include a first substrate SUB1 including the display area DA and the peripheral area PA. The sub-pixel SPX may be disposed in the display area DA. Some components disposed in the display area DA may extend to the peripheral area PA and be disposed in the peripheral area PA.

The sub-pixel SPX may include a pixel circuit layer PCL, a light emitting element LD, an encapsulation layer TFE, and a color conversion layer CCL′ which may be successively disposed on the first substrate SUB1.

In an embodiment, the bank BNK_bot may be disposed on the first substrate SUB1 in the peripheral area PA. The bank BNK_bot may be disposed (e.g., directly disposed) on the third layer EN3 of the encapsulation layer TFE. The bank BNK_bot may be a structure that defines a location at which the color conversion layer CCL′ may be to be supplied.

In an embodiment, the color conversion layer CCL′ may be disposed on the encapsulation layer TFE in the display area DA. The color conversion layer CCL′ may be directly disposed on the third layer EN3 of the encapsulation layer TFE.

In an embodiment, a first protective layer CAP1′ may be disposed on the color conversion layer CCL′. The first protective layer CAP1′ may cover the color conversion layer CCL′ and be disposed to extend to the peripheral area PA.

In an embodiment, the light conversion layer LCPL′ may be disposed on the color conversion layer CCL′. In an embodiment, the light conversion layer LCPL′ may include a second protective layer CAP2, a low refractive layer LRL, a color filter layer CFL, and a second substrate SUB2, which may be successively arranged in the third direction DR3.

In an embodiment, the second substrate SUB2 may be spaced apart from the first substrate SUB1 in the third direction DR3, and may be disposed to face the first substrate SUB1. The second substrate SUB2 may include a first surface facing the first substrate SUB1, and a second surface opposite to the first surface.

In an embodiment, the color filter layer CFL, the low refractive layer LRL, and the second protective layer CAP2 may be successively disposed on the first surface of the second substrate SUB2.

In an embodiment, the color filter layer CFL may be disposed on the first surface (or the lower surface) of the second substrate SUB2. A low refractive layer LRL may be disposed under the color filter layer CFL. The second protective layer CAP2 may be disposed under the low refractive layer LRL.

In an embodiment, in the peripheral area PA, there may be disposed multiple dam structures DAM1 to DAM3, a bank BNK_bot, a first spacer CS″, and a sealant SLT_bot. The dam structures DAM1 to DAM3, the bank BNK_bot, the first spacer CS″, and the sealant SLT_bot may be disposed on the first substrate SUB1.

In an embodiment, the peripheral area PA may include first to third areas PA1 to PA3 that may be arranged in order of the proximity to the display area DA.

In an embodiment, the first area PA1 may be adjacent to the display area DA. Some components that may be disposed in the display area DA may be extended and disposed in the first area PAL. The bank BNK_bot may be disposed in the first area PAL. The bank BNK_bot may be disposed on the encapsulation layer TFE. The first protective layer CAP1′ may extend from the display area DA and cover the bank BNK_bot that may be disposed in the first area PAL.

In an embodiment, the second area PA2 may be spaced apart from the display area DA, with the first area PA1 disposed therebetween. In the second area PA2, there may be disposed the dam structures DAM1 to DAM3. For example, the first to third dam structures DAM1 to DAM3 may be covered by the first layer EN1 and the third layer EN3 of the encapsulation layer TFE and the first protective layer CAP1′. The first layer EN1, the third layer EN3, and the first protective layer CAP1′ may have surface profiles corresponding to the shapes of the first to third dam structures DAM1 to DAM3.

In an embodiment, the third area PA3 may be spaced apart from the display area DA, with the first area PA1 and the second area PA2 disposed therebetween. The third area PA3 may be spaced apart from the display area DA, and may be an outermost area of the display device (e.g., the display device DD of FIG. 1). In the third area PA3, there may be disposed in the first spacer CS″ and the sealant SLT_bot.

In an embodiment, the first spacer CS″ may be disposed on a portion of the encapsulation layer TFE that is extended to the third area PA3. In an embodiment, in the case where the encapsulation layer TFE does not extend to the third area PA3 of the peripheral area PA, the first spacer CS″ may be directly disposed on the pixel circuit layer PCL.

In an embodiment, the first spacer CS″ may have surface characteristics determined by surface tension. The first spacer CS″ may have a semi-elliptical shape. The first spacer CS″ may be formed on the first substrate SUB1 in the third area PA3 by an inkjet printing method. Hence, the first spacer CS″ may have a semi-elliptical shape due to surface tension characteristics.

In an embodiment, the first protective layer CAP1′ may have a surface profile corresponding to the shape of the first spacer CS″.

The sealant SLT_bot may enclose the display area DA, and may be disposed between the first spacer CS″ and the second substrate SUB2. The sealant SLT_bot may be disposed over the first protective layer CAP1′ to overlap the first spacer CS″ in a plan view, and may extend in the third direction DR3 and contact the second substrate SUB2 (or the second protective layer CAP2). The sealant SLT_bot may be disposed in the third area PA3, and may not overlap the damp structures DAM1 to DAM3 in a plan view. However, the disclosure may not be limited to the foregoing embodiment. For example, the sealant SLT_bot may instead extend to the second area PA2 and overlap at least some of the damp structures DAM1 to DAM3.

In an embodiment, the filling layer FL′ may be disposed between the first substrate SUB1 and the second substrate SUB2. The filling layer FL′ may overlap the display area DA, and may extend to the peripheral area PA and contact the sealant SLT_bot. In an embodiment, the filling layer FL′ may include filling material that fills space between the first protective layer CAP1′ of the first substrate SUB1 and the second protective layer CAP2 of the second substrate SUB2. The filling material may include silicon, epoxy, and acrylic thermosetting materials.

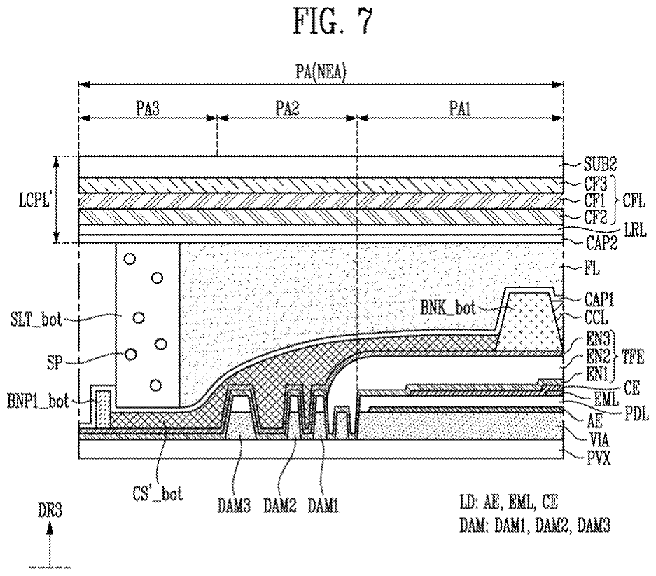

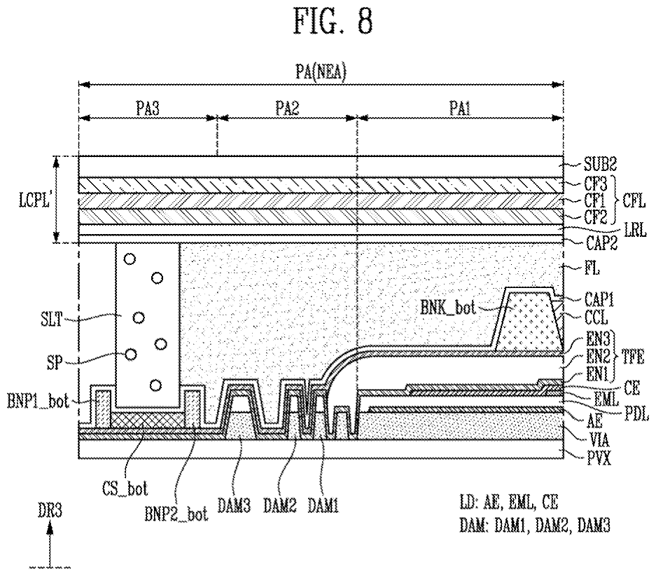

FIGS. 7 and 8 are schematic sectional views illustrating other embodiments of the peripheral area PA of FIG. 6.

The following description with reference to the embodiments of FIGS. 7 and 8 will be focused on differences from the above-mentioned embodiments (e.g., the embodiment of FIG. 6) so as to avoid redundant description.

Referring to FIG. 7, except a first bank pattern BNP1_bot and a first spacer CS′_bot, the remaining components may be identical to or correspond to the components illustrated in FIG. 6.

Referring to FIG. 7, the first spacer CS′ bot and the first bank pattern BNP1_bot may be disposed in the peripheral area PA. In an embodiment, the first spacer CS′_bot and the first bank pattern BNP1_bot may be disposed on the first substrate SUB1. The first bank pattern BNP1_bot may be disposed on the encapsulation layer TFE (or the passivation layer PVX) in the third area PA3. In an embodiment, the first spacer CS′_bot may be disposed on a portion of the encapsulation layer TFE that is disposed between the first bank pattern BNP1_bot and the bank BNK_bot. The first spacer CS′_bot may be disposed to extend from the first area PA1 where the bank BNK_bot is disposed to the third area PA3 where the first bank pattern BNP1_bot is disposed. The first spacer CS′_bot may overlap the dam structures DAM1 to DAM3 in a plan view. The first protective layer CAP1′ may cover the bank BNK_bot, the first spacer CS′_bot, and the first bank pattern BNP1_bot. The first protective layer CAP1′ may have a surface profile corresponding to the shapes of the bank BNK_bot, the first spacer CS′_bot, and the first bank pattern BNP1_bot.

Referring to FIG. 8, except first and second bank patterns BNP1_bot and BNP2_bot and a first spacer CS_bot, the remaining components may be identical to or correspond to the components illustrated in FIG. 6.

Referring to FIG. 8, the first and second bank patterns BNP1_bot and BNP2_bot and the first spacer CS_bot may be disposed on the first substrate SUB1 in the third area PA3 of the peripheral area PA. In an embodiment, the first and second bank patterns BNP1_bot and BNP2_bot may be disposed on the encapsulation layer TFE (or the passivation layer PVX) in the third area PA3 at locations spaced apart from each other. The second bank pattern BNP2_bot may be disposed closer to the display area DA than the first bank pattern BNP1_bot. The first and second bank patterns BNP1_bot and BNP2_bot may be structures that define a location where first spacer CS_bot may be disposed. The first spacer CS_bot may be disposed over the encapsulation layer TFE (or the passivation layer PVX) in an area enclosed by the first and second bank patterns BNP1_bot and BNP2_bot. The first spacer CS_bot may be disposed only in the third area PA3, and may not be disposed in the first or second areas PA1 or PA2.

In an embodiment, the first spacer CS_bot may have surface characteristics determined by surface tension. For instance, the first and second bank patterns BNP1_bot and BNP2_bot may form a meniscus in first spacer CS_bot by raising a portion of a surface film of the first spacer CS_bot adjacent to the first and the second bank patterns BNP1_bot and BNP2_bot, so that the first spacer CS_bot may have a concave surface (or concave meniscus) shape.

In an embodiment, the first protective layer CAP1′ may cover the bank BNK_bot, the first spacer CS_bot, and the first and second bank patterns BNP1_bot and BNP2_bot. The first protective layer CAP1′ may have a surface profile corresponding to the shapes of the bank BNK_bot, the first and second bank patterns BNP1_bot and BNP2_bot, and the first spacer CS_bot.

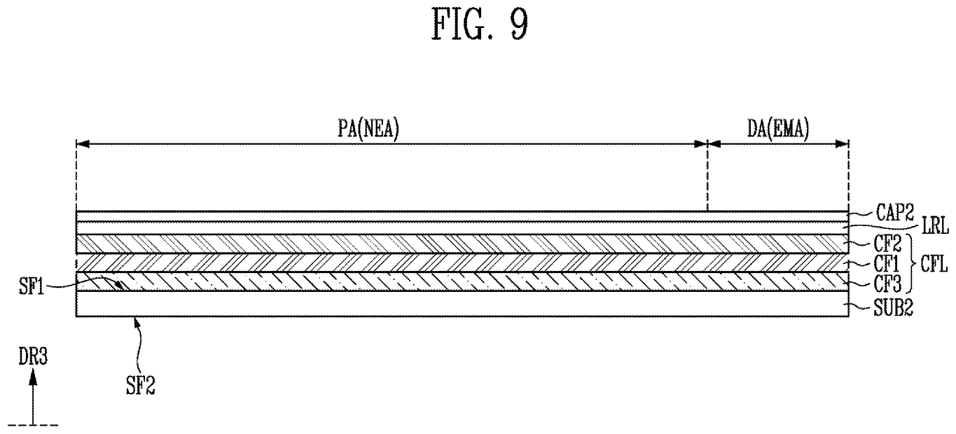

FIGS. 9 to 14 are sectional views schematically illustrating a method of fabricating the display device in accordance with embodiments of the disclosure.

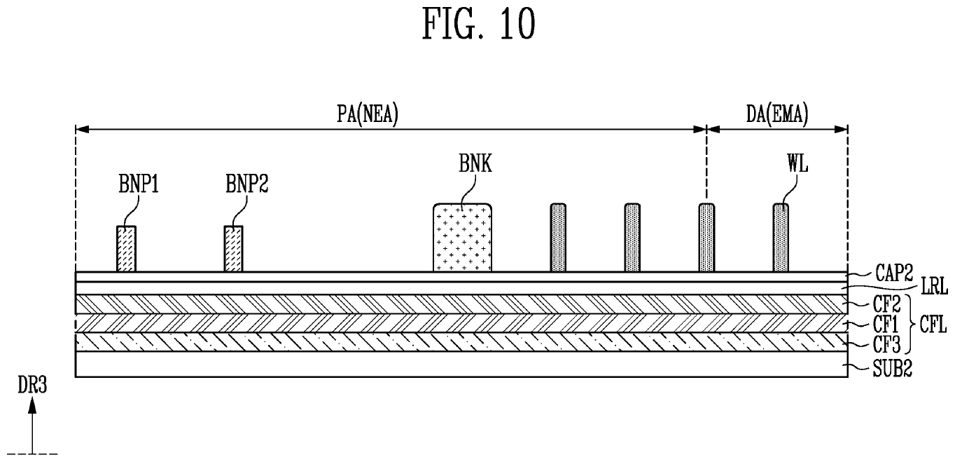

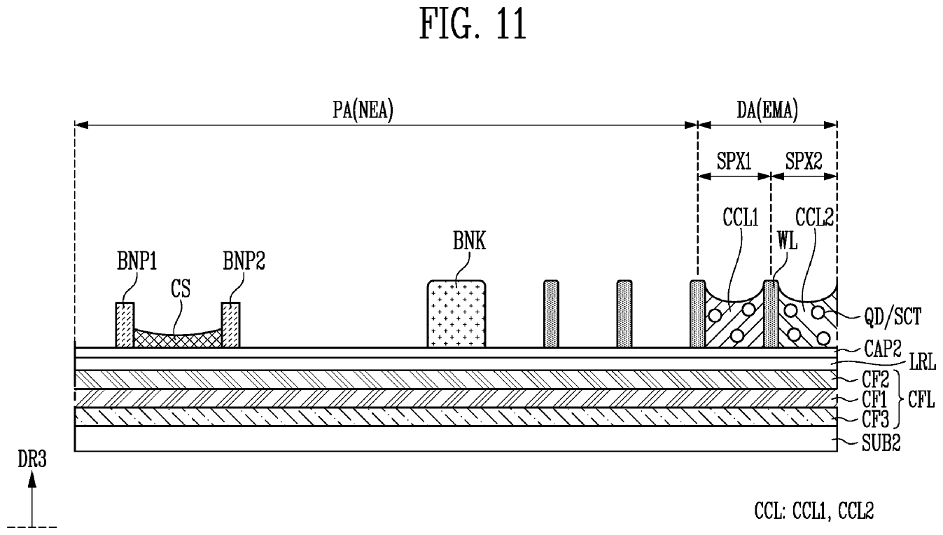

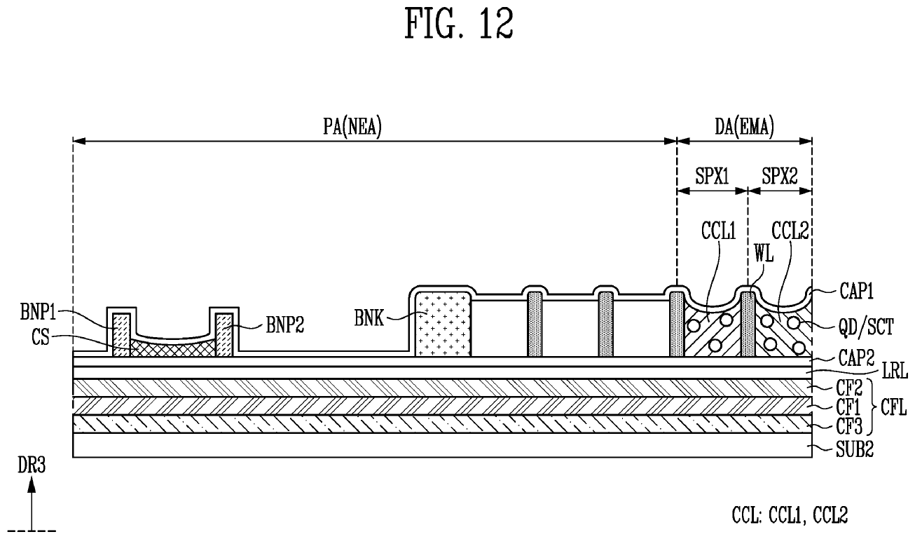

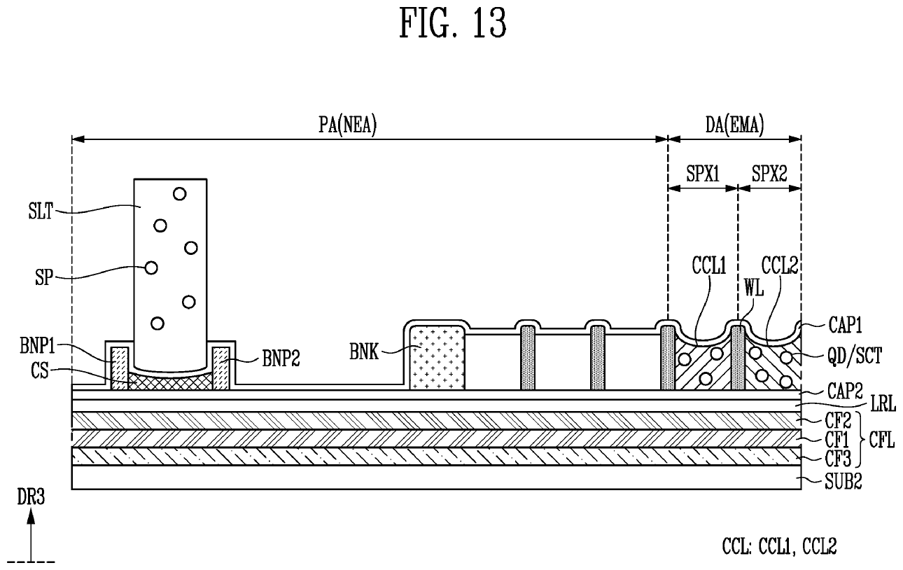

The method of fabricating the display device in accordance with embodiments of the disclosure may include the step of forming the color filter layer CFL on a base substrate (or the second substrate) SUB2 that includes the display area DA and the peripheral area PA disposed on a side of the display area DA (refer to FIG. 9), the step of forming on the color filter layer CFL at least one partition wall WL in the display area DA, and forming at least one bank pattern BNP1 and/or BNP2 in the peripheral area PA (refer to FIG. 10), the step of forming the color conversion layer CCL including multiple color conversion particles in the display area DA, and forming the first spacer CS in the peripheral area PA (refer to FIG. 11), the step of forming the first protective layer CAP1 that covers the color conversion layer CCL and the first spacer CS (refer to FIG. 12), and the step of forming the sealant SLT that overlaps the first spacer CS in a plan view (refer to FIG. 13). The method of fabricating the display device in accordance with embodiments of the disclosure may further include the step of bonding the second substrate SUB2 to the first substrate SUB1 such that the color conversion layer CCL formed on the second substrate SUB2 faces the light emitting element LD formed on the first substrate SUB1.

Referring to FIG. 9, the color filter layer CFL may be formed on the base substrate (or the second substrate) SUB2. In an embodiment, the low refractive layer LRL and the second protective layer CAP2 may be formed successively in the third direction DR3 on the base substrate SUB2.

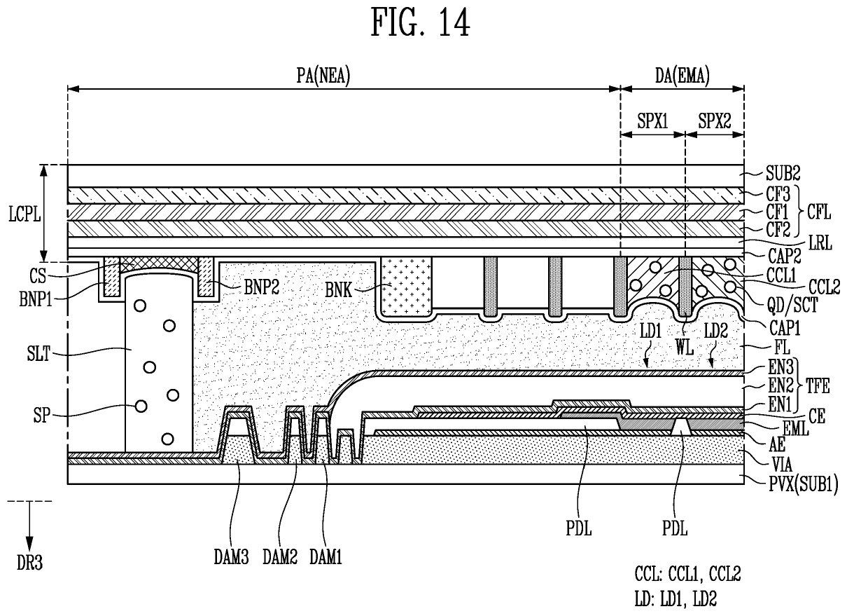

In an embodiment, the base substrate SUB2 may include a first surface SF1 that faces the light emitting element (e.g., the light emitting element LD of FIG. 14) disposed on the first substrate (e.g., the first substrate SUB1 of FIG. 14) to be bonded to the base substrate SUB2, and a second surface SF2 that faces opposite to the first surface SF1. In an embodiment, the color filter layer CFL, the low refractive layer LRL, and the second protective layer CAP2 may be successively formed on the first surface SF1 of the base substrate SUB2.

In an embodiment, the base substrate SUB2 may include the display area DA, and the peripheral area PA disposed on a side of the display area DA. The display area DA may be an area where pixels (e.g., the pixels PXL of FIG. 1) may be disposed. The peripheral area PA may be disposed around the display area DA to enclose the periphery of the display area DA.

In an embodiment, the base substrate SUB2 may be a rigid substrate or a flexible substrate. For example, the rigid substrate may be one or more of a glass substrate, a quartz substrate, a glass ceramic substrate, and a crystalline glass substrate.

Referring to FIG. 10, the partition wall WL may be formed in the display area DA on the color filter layer CFL (or the second protective layer CAP2). At least one bank pattern BNP1 and/or BNP2 may be formed in the peripheral area PA.

In an embodiment, at least one or more bank patterns BNP1 and BNP2 may be formed in the peripheral area PA. The at least one or more bank patterns BNP1 and BNP2 may be spaced apart from each other and disposed on the second protective layer CAP2. The at least one or more bank patterns BNP1 and BNP2 may define an area where the first spacer (e.g., the first spacer CS of FIG. 11) may be disposed. In an embodiment, the at least one or more bank patterns BNP1 and BNP2 may include a first bank pattern BNP1 and a second bank pattern BNP2. The first bank pattern BNP1 and the second bank pattern BNP2 may be disposed at locations spaced apart from the display area DA. The first bank pattern BNP1 may be disposed at a location spaced apart from the display area DA by a distance greater than the second bank pattern BNP2.

In an embodiment, the bank BNK may be formed in a portion of the peripheral area PA adjacent to the display area DA. The bank BNK may be a dam structure for preventing the color conversion layer (e.g., the color conversion layer CCL of FIG. 11) from infiltrating into the peripheral area PA. The bank BNK may be formed between at least one bank pattern BNP1 and/or BNP2 and the partition wall WL.

In an embodiment, the partition wall WL may be formed in the display area DA. The partition wall WL may be formed between adjacent sub-pixels (for example, the first and second sub-pixels SPX1 and SPX2 of FIG. 11) or on a boundary therebetween. The partition wall WL may include an opening that overlaps the sub-pixels SPX1 and SPX2. The opening of the partition wall WL may function as a dam structure for preventing the color conversion layer (e.g., the color conversion layer CCL of FIG. 11) from infiltrating into an adjacent sub-pixel, or may control the supply of a certain amount of the color conversion layer CCL to each of the sub-pixels SPX1 and SPX2.

In an embodiment, at least one bank pattern BNP1 and/or BNP2, the bank BNK, and the partition wall WL may be formed through a same process, and may include a same material. At least one bank pattern BNP1 and/or BNP2, the bank BNK, and the partition wall WL may include inorganic material or organic material.

In an embodiment, at least one bank pattern BNP1 and/or BNP2 may be formed at the same height as the bank BNK and the partition wall WL, but the disclosure may not be limited thereto. In an embodiment, the heights of the bank BNK and the partition wall WL may be approximately 10 m. The height of at least one bank pattern BNP1 and/or BNP2 may be less or greater than approximately 10 m.

Referring to FIG. 11, the color conversion layer CCL including multiple color conversion particles may be formed in the display area DA. In the peripheral area PA, there may be formed the first spacer CS in an area enclosed by at least one bank pattern BNP1 and/or BNP2.

In an embodiment, the color conversion layer CCL may include a first color conversion layer CCL1 disposed corresponding to the first sub-pixel SPX1, and a second color conversion layer CCL2 disposed corresponding to the second sub-pixel SPX2. Each of the first color conversion layer CCL1 and the second color conversion layer CCL2 may include color conversion particles corresponding to a certain color. The color conversion layer CCL may include multiple color conversion particles dispersed in certain matrix material such as base resin. It is to be appreciated that the arrangement of FIG. 11 shows two differently colored color conversion layers while FIGS. 4 and 6 only show one color conversion layer because FIGS. 4 and 6 show only one sub-pixel in the display area due to the direction of the cross section.

In an embodiment, the first spacer CS may be formed in an area enclosed by the first and second bank patterns BNP1 and BNP2.

In an embodiment, the color conversion layer CCL and the first spacer CS may be formed through a same process. The color conversion layer CCL and the first spacer CS may be formed by an inkjet printing method, in which ink containing color conversion particles may be sprayed. In an embodiment, the first spacer CS and the color conversion layer CCL may include a same material.

In an embodiment, the height of the first spacer CS1 may be determined based on design conditions of the display device. The height of the first spacer CS1 may be controlled by adjusting the amount of ink sprayed.

In an embodiment, the color conversion layer CCL and the first spacer CS may have surface characteristics determined by surface tension. In an embodiment, the bank patterns BNP1 and BNP2 and the partition wall WL may form a meniscus in the color conversion layer CCL and in the first spacer CS respectively by raising a surface film of the color conversion layer CCL and a surface of the first spacer CS adjacent to partition wall WL and first and second bank patterns BNP1 and BNP2 respectively. The surface shape of the color conversion layer CCL may have a concave surface shape. Likewise, the first and second bank patterns BNP1 and BNP2 may raise a surface film of the first spacer CS, so that the first spacer CS may also have a concave surface shape.

Referring to FIG. 12, the first protective layer CAP1 may be formed on an overall surface of the second substrate SUB2. In an embodiment, the first protective layer CAP1 may cover at least one bank pattern BNP1 and/or BNP2, the first spacer CS, the second protective layer CAP2, the bank BNK, the color conversion layer CCL, and the partition wall WL. Prior to the formation of the first protective layer CAP1, a filler material may be deposited to fill spaces between partition walls WL formed in the peripheral area. The first protective layer CAP1 may have a surface profile corresponding to the shapes of at least one bank pattern BNP1 and/or BNP2, the first spacer CS, the second protective layer CAP2, the bank BNK, the color conversion layer CCL, and the partition wall WL.

Referring to FIG. 13, the sealant SLT may be formed on a portion of the first protective layer CAP1 that overlaps the first spacer CS. The sealant SLT may include UV-curable material.

In an embodiment, the sealant SLT may be formed by dispenser equipment. The sealant SLT may be mixed with material capable of absorbing water. In an embodiment, multiple support particles SP may be disposed to reinforce support force of the sealant SLT.

Referring to FIG. 14, after the sealant SLT is formed in the peripheral area PA and on the second substrate SUB2, the second substrate SUB2 may be bonded to the first substrate SUB1 on which the light emitting element LD and the encapsulation layer TFE are formed.

In an embodiment, the second substrate SUB2 may be bonded to the first substrate SUB1 in such a way that the color conversion layer CCL formed on the second substrate SUB2 faces the light emitting element LD formed on the first substrate SUB1.

In an embodiment, after the second substrate SUB2 is bonded to the first substrate SUB1, the filling layer FL may be disposed so that it extends from the display area DA to the peripheral area PA where the sealant SLT is disposed. Here, the disclosure may not be limited to the foregoing embodiment. For example, before the second substrate SUB2 may be bonded to the first substrate SUB1, the filling layer FL may be formed on the first substrate SUB1 by an inkjet printing method. In an embodiment, ultraviolet (UV) rays may be applied to the first and second substrates SUB1 and SUB2 so that the filling layer FL can be sealed.

According to the method of fabricating the display device in accordance with embodiments of the disclosure, the height of the first spacer CS may be flexibly controlled depending on the spacing between the first substrate SUB1 and the second substrate SUB2 based on the design conditions of the display device (e.g., the size or structure of the display device). The height of the first spacer CS may be adjusted according to the inkjet printing method without the need for additional equipment.

In the display device and the method of fabricating the display device in accordance with embodiments of the disclosure, the first spacer CS may be disposed in an area that overlaps the sealant SLT, so that the restorative stress of the sealant SLT can be reduced. As a result, the spacing between the first substrate SUB1 and the second substrate SUB2 may be secured. Furthermore, as the first spacer CS and the color conversion layer CCL can be formed using a same process and using a same material, the number of processing steps may be shortened, and material costs may be reduced.

The first spacer CS may serve to mitigate stress on the sealant SLT during a process of bonding the second substrate SUB2 to the first substrate SUB1, thus minimizing (or preventing) occurrence of cracks or the like.

A display device in accordance with embodiments of the disclosure includes a spacer that overlaps a sealant in a peripheral area, thus aiming to minimize changes in the spacing between a top substrate and a bottom substrate in the peripheral area. Hence, the reliability of the display device may improve and the display device may be prevented from deteriorating due to changes in the spacing between the top substrate and the bottom substrate in the peripheral area.

Furthermore, the height of the spacer may be flexibly adjusted depending on processing conditions of the display device without using separate additional equipment. Therefore, the efficiency of the process of fabricating the display device may be improved.

Furthermore, in a method of fabricating the display device in accordance with embodiments of the disclosure, the spacer and a color conversion layer may be formed with a same material and a same process, resulting in reduced processing time and material consumption, thus improving processing efficiency.

However, effects of the disclosure may not be limited to the above-described effects, and various modifications may be possible without departing from the spirit and scope of the disclosure.

While embodiments of the disclosure have been described above, those skilled in the art will appreciate that various modifications, additions and substitutions may be possible, without departing from the scope and spirit of the disclosure claimed in the appended claims.

What is claimed is:

1. A display device, comprising:
a first substrate including a display area and a peripheral area disposed on a side of the display area;
a second substrate disposed to face the first substrate, the second substrate including a first surface facing the first substrate, and a second surface opposite to the first surface;
a pixel circuit layer disposed on the first substrate;
a light emitting element disposed on the pixel circuit layer and in the display area;
a color conversion layer disposed on the first surface of the second substrate, the color conversion layer overlapping the display area in a plan view, the color conversion layer converting a wavelength of light emitted from the light emitting element;
at least one bank pattern disposed on the first surface of the second substrate, the at least one bank pattern overlapping the peripheral area in a plan view;
a first spacer disposed on the first surface of the second substrate, the first spacer enclosed by the at least one bank pattern;
a first protective layer overlapping the color conversion layer in a plan view, the at least one bank pattern, and the first spacer; and
a sealant overlapping at least a portion of the first spacer in a plan view.

2. The display device according to claim 1, wherein
the color conversion layer includes a plurality of color conversion particles, and
the first spacer and the plurality of color conversion particles are comprised of a same material.

3. The display device according to claim 1, further comprising:
at least one dam structure disposed on the pixel circuit layer and in the peripheral area, wherein
the at least one dam structure is disposed closer to the display area than the sealant, and
the sealant and the at least one dam structure do not overlap in a plan view.

4. The display device according to claim 3, wherein the first spacer and the at least one dam structure do not overlap in a plan view.

5. The display device according to claim 3, further comprising:
a bank disposed on the first surface of the second substrate, wherein
the peripheral area includes first to third areas arranged in order of proximity to the display area,
the bank overlaps the first area of the peripheral area in a plan view, and
the at least one dam structure is disposed in the second area of the peripheral area.

6. The display device according to claim 5, wherein
the at least one bank pattern includes a first bank pattern overlapping the third area of the peripheral area in a plan view and enclosing at least a portion of the first spacer, and
the first protective layer covers the bank and the first bank pattern.

7. The display device according to claim 6, wherein the first spacer is disposed between the bank and the first bank pattern.

8. The display device according to claim 6, wherein
the at least one bank pattern further includes a second bank pattern overlapping the third area of the peripheral area in a plan view,
the second bank pattern being disposed closer to the display area than the first bank pattern,
the second bank pattern being spaced apart from the first bank pattern, and
the first spacer being disposed between the first bank pattern and the second bank pattern.

9. The display device according to claim 8, further comprising:
a second spacer disposed on the first surface of the second substrate, the second spacer being disposed between the second bank pattern and the bank.

10. The display device according to claim 8, further comprising:
a second spacer, a third spacer and a fourth spacer disposed on the first surface of the second substrate, wherein
the at least one bank pattern further includes a third bank pattern and a fourth bank pattern overlapping the second area of the peripheral area in a plan view,
the third bank pattern and the fourth bank pattern are each spaced apart from the second bank pattern,
the second spacer is disposed between the second bank pattern and the third bank pattern,
the third spacer is disposed between the third bank pattern and the fourth bank pattern, and
the fourth spacer is disposed between the fourth bank pattern and the bank.

11. A display device, comprising:
a first substrate including a display area and a peripheral area disposed on a side of the display area;
a pixel circuit layer disposed on the first substrate;
a light emitting element disposed on the pixel circuit layer and in the display area;
a color conversion layer disposed on the light emitting element and in the display area, the color conversion layer converting a wavelength of light emitted from the light emitting element;
a spacer disposed on the pixel circuit layer and in the peripheral area;
a first protective layer disposed on the first substrate, the first protective layer covering the color conversion layer and the spacer; and
a sealant overlapping at least a portion of the spacer in a plan view.

12. The display device according to claim 11, wherein
the color conversion layer includes a plurality of color conversion particles, and
the spacer and the plurality of color conversion particles are comprised of a same material.

13. The display device according to claim 11, further comprising:
at least one dam structure disposed in the peripheral area, the at least one dam structure being closer to the display area than the sealant.

14. The display device according to claim 13, wherein the spacer covers the at least one dam structure in a plan view.

15. The display device according to claim 13, wherein the spacer does not overlap the at least one dam structure in a plan view.

16. The display device according to claim 15, wherein the spacer has a semi-elliptical shape.

17. The display device according to claim 13, further comprising:
an encapsulation layer disposed in the display area, the encapsulation layer overlapping the light emitting element in a plan view, the encapsulation layer extending to and being disposed in the peripheral area; and
at least one bank pattern disposed on the encapsulation layer and in the peripheral area.

18. The display device according to claim 17, further comprising:
a bank to partition the peripheral area from the display area, wherein
the peripheral area includes first to third areas arranged in order of proximity to the display area,
the bank being disposed in the first area,
the at least one bank pattern includes a first bank pattern disposed in the third area, the at least one bank pattern enclosing at least a portion of the spacer, and
the first protective layer covers the bank and the first bank pattern.

19. The display device according to claim 18, wherein
the at least one dam structure is disposed in the second area,
the at least one bank pattern further includes a second bank pattern disposed in the third area and in an area adjacent to the dam structure, and
the spacer is disposed between the first bank pattern and the second bank pattern.

20. The display device according to claim 19, wherein heights of the first bank pattern and the second bank pattern are lower than a height of the bank.

21. The display device according to claim 11, further comprising:
a filling layer disposed in the display area and extending from an inside of the sealant; and
a light conversion layer disposed on the sealant and the filling layer,
wherein the light conversion layer comprises a second protective layer, a low refractive layer, a color filter layer, and a second substrate that are successively disposed in a direction.

22. A method of fabricating a display device, the method comprising:
providing a base substrate including a display area and a peripheral area disposed at a side of the display area;
forming a color filter layer on the base substrate;
forming at least one partition wall on the color filter layer and in the display area;
forming at least one bank pattern on the color filter layer and in the peripheral area;
forming a color conversion layer in the display area, the color conversion layer including a plurality of color conversion particles;
forming a spacer in the peripheral area and in an area enclosed by the at least one bank pattern;
forming a protective layer that covers the color conversion layer and the spacer; and
forming a sealant on the protective layer, the protective layer overlaps the spacer in a plan view.

23. The method according to claim 22, wherein the spacer and the color conversion layer are formed in a same process.
